(19) United States
(12) Patent Application Publication
(10) Pub. No.: US 2023/0250314 A1
(43) Pub. Date: Aug. 10, 2023

(54) COMPOSITION FOR FORMING A COATING FILM FOR REMOVING FOREIGN MATTERS

(71) Applicant: NISSAN CHEMICAL CORPORATION, Tokyo (JP)

(72) Inventors: Takahiro KISHIOKA, Toyama-shi (JP); Yuki USUI, Toyama-shi (JP); Shunsuke MORIYA, Toyama-shi (JP)

(73) Assignee: NISSAN CHEMICAL CORPORATION, Tokyo (JP)

(21) Appl. No.: 18/015,659

(22) PCT Filed: Jul. 20, 2021
(86) PCT No.: PCT/JP2021/027066

§ 371 Date: Jan. 11, 2023

(30) Foreign Application Priority Data
Jul. 21, 2020 (JP) 2020-124575

(51) Int. Cl. C09D 201/06; H01L 21/56

(52) U.S. Cl. CPC C09D 201/06; H01L 21/568; H01L 2221/68386

(57) ABSTRACT

A simple method for removing foreign substances that are formed on a substrate during a semiconductor device production process and a composition for forming a coating film for foreign substance removal, said coating film being used in the above-described method. A composition for forming a coating film for foreign substance removal, said composition containing a polymer and a solvent and being capable of forming a coating film that dissolves in a developer liquid, wherein: the polymer is selected from among phenolic novolacs, polyhydroxystyrene derivatives and carboxylic acid-containing polymers; and the polymer is contained in an amount of 50% by mass or more relative to the total solid content in the composition.

### TECHNICAL FIELD

The present invention relates to a composition for forming a coating film for removing foreign matters, a method for removing foreign matters on a substrate, a method for treating a substrate, and a method for producing a laminated substrate, in which foreign matters formed on a substrate can be removed by a simple and easy method. The present invention relates to a composition for forming a coating film for removing foreign matters, which is preferably used in the step of temporary bonding of semiconductor wafer in the production of a semiconductor device.

### BACKGROUND ART

In the production of a semiconductor device, with respect to the so-called post-step in particular, studies have been made on the process, in which a semiconductor substrate (wafer) is bonded to a supporting substrate, then subjected to, e.g., back-grinding (grinding) and wiring formation steps, and subsequently the supporting substrate is peeled off, to obtain a desired semiconductor substrate.

When bonding a wafer to a supporting substrate, the wafer is bonded using a bonding agent (such as a liquid composition containing a polymer, a back-grinding tape, or a dicing tape) having a resistance to the subsequent steps (heating step and chemical treatment step), and then the step of peeling the semiconductor substrate off is performed. In this instance, the bonding layer included in the bonding agent likely remains on the substrate as foreign matters (residue). Such a phenomenon remarkably occurs especially when a bonding layer is formed directly on the surface of a semiconductor substrate having wiring and others previously formed on a substrate. There are some cases in which the foreign matters cannot be completely removed even when, for example, cleaning is conducted using, e.g., a known organic solvent or liquid chemical agent.

There is also a problem of removing foreign matters already present on a substrate for semiconductor production. For example, Patent Literature 2 and Patent Literature 3 disclose compositions for forming substrate treatment films and methods for treating substrates, which can efficiently remove minute particles from a substrate surface and easily remove the formed substrate treatment film from the substrate surface, in a process for forming a substrate treatment film on the surface of the semiconductor substrate and removing foreign matters from this substrate surface.

A composition for forming a coating film for removing foreign matters using a polyamide acid material is disclosed (Patent Literature 1).

### CITATION LIST

### Patent Literature

Patent Literature 1: WO 2018/159665 A1

Patent Literature 2: WO 2017/056746 A1

Patent Literature 3: WO 2020/008965 A1

### SUMMARY OF INVENTION

### Technical Problem

A problem to be solved by the present invention is to provide a simple and easy method for removing foreign matters formed on a substrate, foreign matters already present on a semiconductor substrate, in the step of temporary bonding of semiconductor wafer in the production of a semiconductor device, for example, and to provide a composition for forming a coating film for removing foreign matters used in such a method.

The application of the coating film for removing foreign matters according to the present invention is not limited to the above-mentioned temporary bonding step as long as the coating film is used for removing foreign matters on a substrate.

### Solution to Problem

The present invention embraces the followings.

[1] A composition for forming a coating film for removing foreign matters, which comprises a polymer and a solvent, and is capable of forming a coating film that is soluble in a developer,
wherein the polymer is selected from a phenolic hydroxy group-containing polymer and a carboxy group-containing polymer, and the composition contains the polymer in an amount of 50% by mass or more relative to the total solid content in the composition.

[2] The composition according to [1], wherein the phenolic hydroxy group-containing polymer is a phenolic novolac or a polyhydroxystyrene derivative.

[3] The composition according to [1], wherein the carboxy group-containing polymer is selected from (meth)acrylic resin, polyvinyl benzoic acid or carboxymethyl cellulose.

[4] The composition according to any one of [1] to [3], wherein the composition comprises a cross-linking agent and/or an additive.

[5] The composition according to [4], wherein the cross-linking agent comprises an epoxy group.

[6] A coating film for removing foreign matters, which is a baked product of an applied film of the composition according to any one of [1] to [5].

[7] A method for removing foreign matters, comprising the steps of:
applying the composition according to any one of [1] to [5] onto a substrate and baking the applied composition to form a coating film;
allowing foreign matters to be formed on the coating film, and
removing the coating film together with the foreign matters using a developer.

[8] The method according to [7], wherein the step of allowing foreign matters to be formed includes the step of forming a bonding layer on the coating film, and the step of peeling the bonding layer off thereafter.

[9] The method according to [8], wherein the foreign matters are a peeled residue of the bonding layer.

[10] A method for treating a substrate, comprising the steps of:
applying the composition according to any one of [1] to [5] onto a first substrate and baking the applied composition to form a coating film;
forming a bonding layer on the coating film;
temporarily bonding a second substrate to the first substrate through the bonding layer;
peeling the second substrate off from the first substrate; and
removing the coating film remaining on the first substrate after peeling off the second substrate, together with the bonding layer, using a developer.

[11] A method for producing a laminated substrate, comprising the steps of:
applying the composition according to any one of [1] to [5] onto a first substrate and baking the applied composition to form a coating film;
forming a bonding layer on the coating film, and
bonding a second substrate to the first substrate.

[12] A composition, which is used for removing foreign matters on a substrate for semiconductor production,
wherein the composition comprises a polymer and a solvent, the polymer is selected from a phenolic hydroxy group-containing polymer and a carboxy group-containing polymer, and the composition contains the polymer in an amount of 50% by mass or more relative to the total solid content in the composition.

[13] The composition according to [12], wherein the composition contains a cross-linking agent and/or an additive.

[14] A composition, which is used for removing foreign matters on a substrate for semiconductor production,
wherein the composition comprises a polymer and a solvent, and the polymer is a polyamide acid having a structural unit derived from (a) a tetracarboxylic dianhydride compound and (b) a diamine compound having at least one carboxyl group.

[15] A method for removing foreign matters, comprising the steps of:
applying the composition according to any one of [12] to [14] onto a substrate carrying foreign matters and baking the applied composition to form a coating film containing foreign matters, and
removing the coating film together with the foreign matters using a developer.

### Advantageous Effects of Invention

Particularly, in the step of temporary bonding of wafer for semiconductor wafer, the coating film for removing foreign matters (coating film for removing foreign matters) of the present invention is preliminarily formed on a substrate (substrate for processing), the substrate is bonded to a supporting substrate using a bonding layer, then the supporting substrate is peeled off from the substrate in the wafer peeling step, and then the substrate is subjected to cleaning using a developer, so that both the coating film for removing foreign matters according to the present invention and the foreign matters on the coating film for removing foreign matters can be simultaneously and completely removed. Moreover, by removing from the substrate surface, a substrate treatment film containing foreign matters on the surface of a substrate for semiconductor production for some reason, the foreign matters can be easily removed from the substrate for semiconductor production. This markedly reduces defective products caused due to foreign matters in the semiconductor device production, and contributes to an improvement of the yield of high quality wafers.

Particularly, when used in the semiconductor step of temporary bonding of wafer, the coating film for removing foreign matters according to the present invention has a resistance to the semiconductor substrate processing process (by heat and chemicals) subsequent to the wafer temporarily bonding.

### DESCRIPTION OF EMBODIMENTS

### A Composition for Forming a Coating Film for Removing Foreign Matters

The composition for forming a coating film for removing foreign matters according to the present invention comprises a polymer and a solvent and is capable of forming a coating film that is soluble in a developer, in which the polymer is selected from phenolic hydroxy group-containing polymers and carboxy group-containing polymers. These polymers are soluble in the developer.

It is preferred that the phenolic hydroxy group-containing polymer is a phenolic novolac or a polyhydroxystyrene derivative.

It is preferred that the carboxy group-containing polymer is selected from (meth)acrylic resin, polyvinyl benzoic acid or carboxymethyl cellulose.

Moreover, the composition is characterized by containing the polymer in an amount of 50% by mass or more to the total solid content in the composition.

Preferably, it contains the polymer in an amount of 60% by mass or more, 70% by mass or more, 80% by mass or more, or 90% by mass or more.

Phenolic novolacs (novolac resins) that are conventionally used in positive photosensitive materials and the like may be used without limitation, and the examples thereof include resins obtained by polymerizing phenols and aldehydes in the presence of an acid catalyst, and the like.

Examples of phenols listed above include phenols; cresols such as o-cresol, m-cresol, and p-cresol; xylenols such as 2,3-xylenol, 2,4-xylenol, 2,5-xylenol, 2,6-xylenol, 3,4-xylenol, and 3,5-xylenol; alkylphenols such as o-ethylphenol, m-ethylphenol, p-ethylphenol, 2-isopropylphenol, 3-isopropylphenol, 4-isopropylphenol, o-butylphenol, m-butylphenol, p-butylphenol, p-tert-butylphenol; trialkylphenols such as 2,3,5-trimethylphenol, 3,4,5-trimethylphenol; polyvalent phenols such as resorcinol, catechol, hydroquinone, hydroquinone monomethyl ether, pyrogallol, and fluoroglycinol; alkyl polyvalent phenols such as alkylresorcinol, alkylcatechol, and alkylhydroquinone (all alkyl groups are 1 to 4 carbon atoms); α-naphthol, β-naphthol, hydroxydiphenyl, and bisphenol A. These phenols may be used each alone or two or more thereof in combination.

Examples of the above aldehydes include formaldehyde, paraformaldehyde, furfural, benzaldehyde, nitrobenzaldehyde, acetaldehyde, and the like. These aldehydes may be used each alone or two or more thereof in combination.

The above acid catalysts include, for example, inorganic acids such as hydrochloric acid, sulfuric acid, nitric acid, phosphoric acid, phosphorous acid; organic acids such as formic acid, oxalic acid, acetic acid, diethyl sulfuric acid, and paratoluenesulfonic acid; metal salts such as zinc acetate.

The phenolic novolac of the present application may be a naphthol cresol novolac polymerized with α-naphthol or β-naphthol.

### Polyhydroxystyrene Derivative

The polyhydroxystyrene derivatives of the present application are obtained by polymerizing hydroxystyrene having substituents. The following unit structure is preferred:

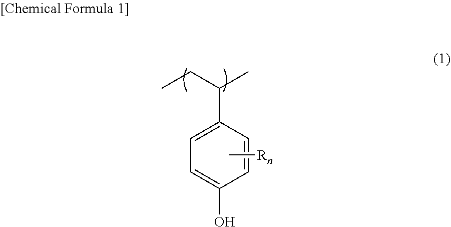

In Formula (1), R represents a halogen atom, a carboxyl group, a nitro group, a cyano group, a methylenedioxy group, an acetoxy group, a methylthio group, an amino group or an alkoxy group with 1 to 9 carbon atoms. n represents an integer from 1 to 4.

When n is 2 or more, the n number of R may be the same or different.

Examples of the above-mentioned halogen atom include fluorine atom, chlorine atom, bromine atom, and iodine atom.

Examples of the above-mentioned alkoxy groups having 1 to 9 carbon atoms include a methoxy group, an ethoxy group, an n-propoxy group, an i-propoxy group, an n-butoxy group, an i-butoxy group, an s-butoxy group, a t-butoxy group, an n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2,-trimethyl-n-propoxy group, 1-ethyl-1-methyl-n-propoxy group, 1-ethyl-2-methyl-n-propoxy group, an n-heptyloxy group, an n-octyloxy group, an n-nonyloxy group, and the like.

### (Meth) Acrylic Resin

(Meth) acrylic resin of the present application that is conventionally used in positive photosensitive materials and the like may be used without limitation, and the examples thereof include resins obtained by polymerizing polymerizable monomers having (meth)acrylic groups in the presence of an radical polymerization initiator, and the like.

Examples of the above-mentioned polymerizable monomers having (meth)acrylic groups include (meth)acrylic acid alkyl esters such as (meth)acrylic acid methyl ester, (meth)acrylic acid ethyl ester, (meth)acrylic acid propyl ester, (meth)acrylic acid butyl ester, (meth)acrylic acid pentyl ester, (meth)acrylic acid hexyl ester, (meth)acrylic acid heptyl ester, (meth)acrylic acid octyl ester, (meth)acrylic acid 2-ethylhexyl ester, (meth)acrylic acid nonyl ester, (meth)acrylic acid decyl ester, (meth)acrylic acid undecyl ester, (meth)acrylic acid dodecyl ester, (meth)acrylic acid trifluoroethyl ester, and (meth)acrylic acid tetrafluoropropyl ester; acrylamides such as diacetone acrylamide; (meth)acrylic acid tetrahydrofurfuryl ester, (meth)acrylic acid dialkylaminoethyl ester, (meth)acrylic acid glycidyl ester, (meth)acrylic acid, α-bromo(meth)acrylic acid, α-chloro(meth)acrylic acid, β-furyl(meth)acrylic acid, β-styryl(meth)acrylic acid, and the like. These polymerizable monomers having (meth)acrylic groups may be used each alone or two or more thereof in combination.

Examples of the above-mentioned radical polymerization initiators include, organic peroxides such as benzoyl peroxide, dicumyl peroxide, and dibutyl peroxide; azobis compounds such as azobisisobutyronitrile and azobisvaleronitrile.

In addition to polymerizable monomers having the (meth)acrylic group, the above-mentioned acrylic resin may be those in which one or two types or more of the following compounds being polymerized with: polymerizable styrene derivatives substituted at the α-position or aromatic ring, such as styrene, vinyltoluene, and α-methylstyrene; esters of vinyl alcohol such as acrylonitrile, and vinyl-n-butyl ether; maleic acid, maleic anhydride, maleic acid monoesters such as monomethyl maleate, monoethyl maleate, and monoisopropyl maleate; polymerizable monomers such as fumaric acid, silicic acid, α-cyanosilicylic acid, itaconic acid, and crotonic acid.

In the present specification, “(meth)acrylic” means both “acrylic” and “methacrylic”.

### Polyvinyl Benzoic Acid

The polyvinylbenzoic acid of the present application is obtained, for example, by polymerizing 4-vinylbenzoic acid shown below by a known method.

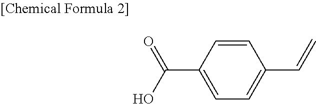

### Carboxymethylcellulose

The carboxymethyl cellulose of the present application has the structure shown below.

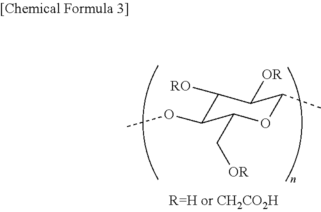

(In the formula, n represents the number of repeat units.)

The composition for forming a coating film for removing foreign matters according to the present application may also contain a polymer that is a polyamide acid having a structural unit derived from (a) a tetracarboxylic dianhydride compound and (b) a diamine compound having at least one carboxyl group, as described in WO 2018/159665. The polymer may be a polyamide acid having a structural unit derived from (a) a tetracarboxylic dianhydride compound and (b) a diamine compound having at least one carboxyl group and a structural unit derived from (a) a tetracarboxylic dianhydride compound and (c) a diamine compound different from (b).

The (c) diamine compound may be a diamine compound without carboxyl groups.

The polyamic acid contained in the composition for forming a coating film for removing foreign matters according to the present invention includes polyamic acids of the following formulae (29) to (41) (wherein p₁, p₂, p₃, and p₄ represent a ratio of each structure in the polyamic acid), for example. Formulae (29) to (36) are a polyamic acid produced from one tetracarboxylic dianhydride compound and two diamine compounds; formulae (37) and (38) are a polyamic acid produced from two tetracarboxylic dianhydride compounds and one diamine compound; formula (39) is a polyamic acid produced from two tetracarboxylic dianhydride compounds and two diamine compounds; and formulae (40) and (41) are a polyamic acid produced from one tetracarboxylic dianhydride compound and one diamine compound.

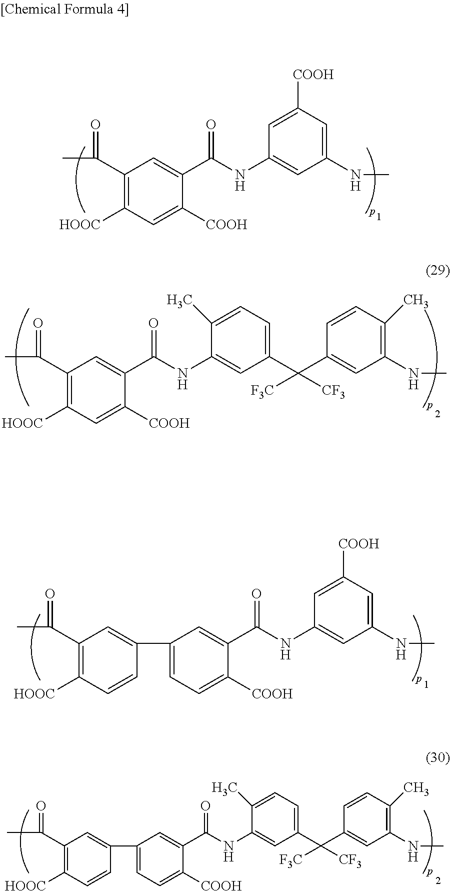

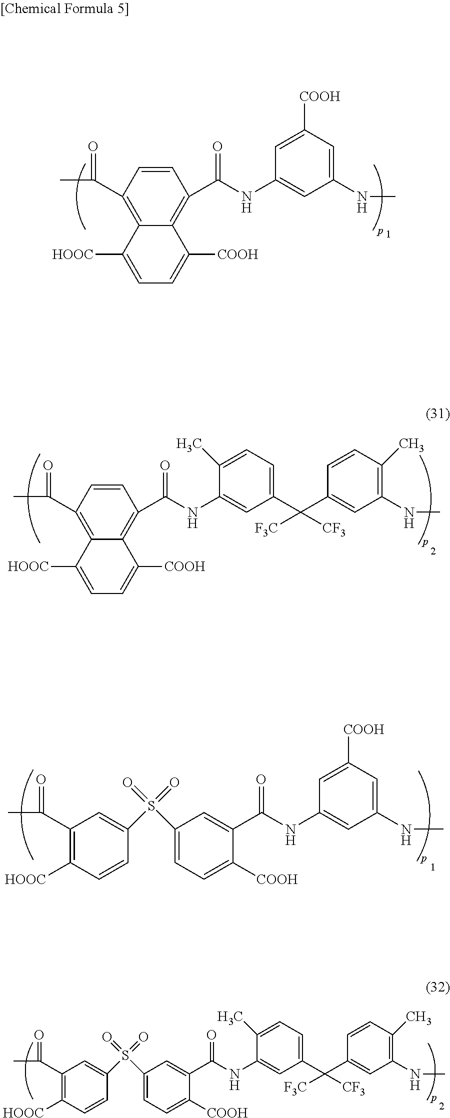

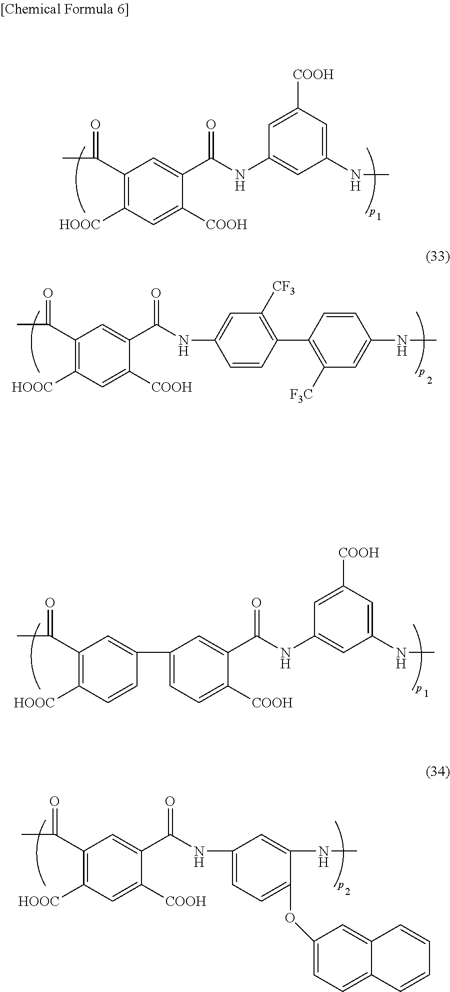

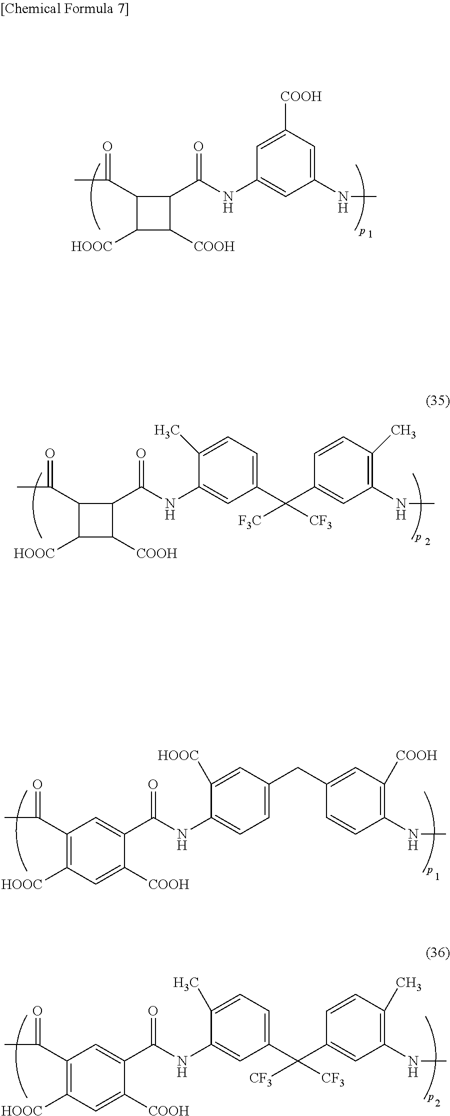

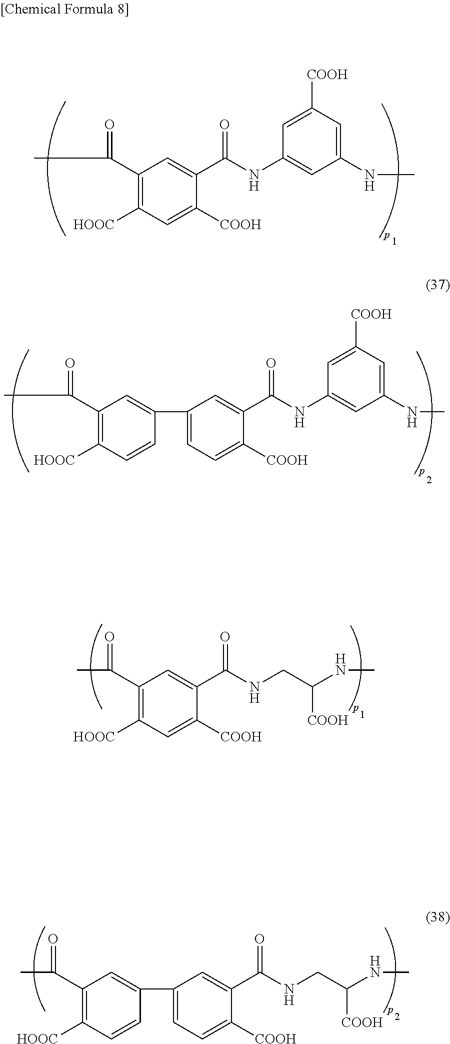

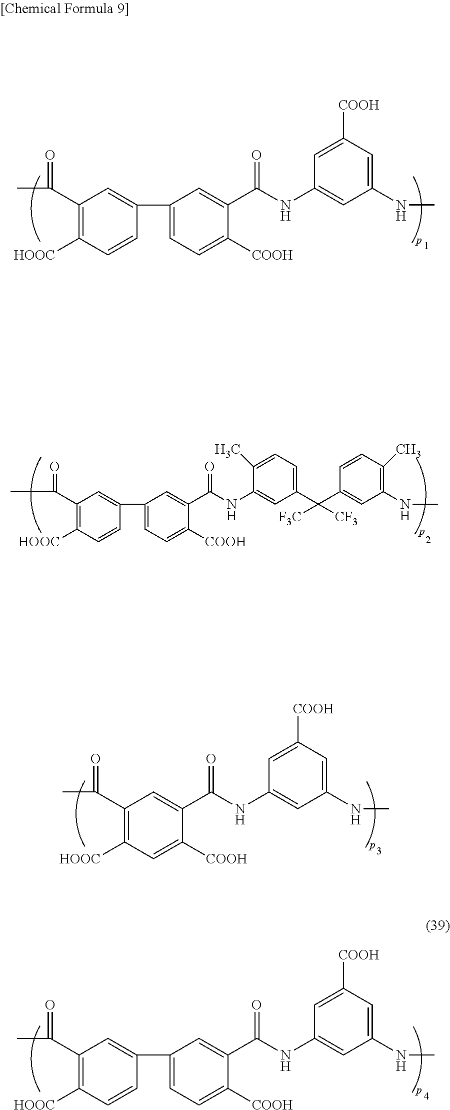

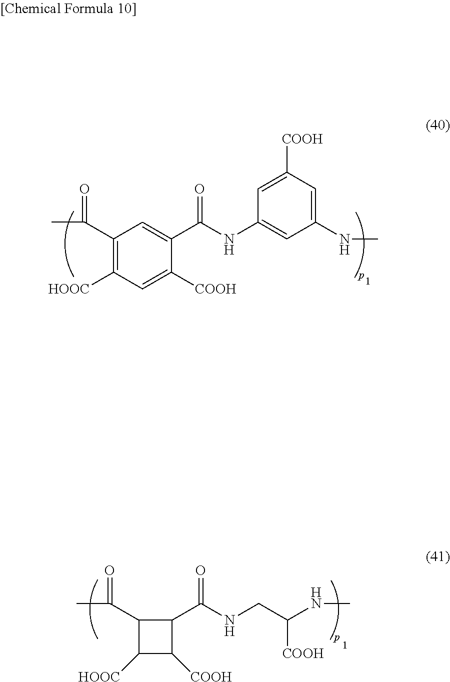

The contents of WO 2018/159665 are incorporated herein in their entirety to the same extent as if explicitly stated.

The weight average molecular weight of the polymer of the present application is, for example, within the range of 1,000 to 100,000 or 1,000 to 50,000, preferably 2,000 to 50,000, by polystyrene conversion, as measured by gel permeation chromatography (GPC). When the weight average molecular weight is 1,000 or less, the solubility of the coating film for removing the formed foreign matters in the solvent used in the bonding agent layer may sometimes be increased, which could cause intermixing (mixing of layers) of the coating film with the bonding agent layer. When the weight average molecular weight is 100,000 or more, the solubility of the coating film for removing the formed foreign matters in a developer may sometimes become insufficient, so that a residue would remain after the development.

### Solvent

The composition for forming a coating film for removing foreign matters according to the present invention may be easily prepared by uniformly mixing the above-mentioned components, and it is used in a solution state, in which the components are dissolved in an appropriate solvent. Such a solvent includes, for example, ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, or N-methylpyrrolidone. These solvents may be used each alone or two or more thereof in combination. A high boiling-point solvent, such as propylene glycol monobutyl ether or propylene glycol monobutyl ether acetate, may be mixed into the above solvent.

The solution of the resin composition for forming a coating film for removing foreign matters prepared as mentioned above is preferably subjected to filtration using, for example, a filter having a pore diameter of about 0.2 μm, before use. The prepared solution of the resin composition for forming a coating film for removing foreign matters is superior in long-term storage stability at room temperature.

There is no particular limitation to the ratio of the solid content of the composition for forming a coating film for removing foreign matters according to the present invention as long as the components are uniformly dissolved. However, for example, the ratio of the solid content of the composition ranges from 0.5 to 50% by mass, or, for example, 1 to 30% by mass. The “solid” means a component left behind the subtraction of the solvent component from the total components of the composition for forming a coating film for removing foreign matters.

In the present invention, the foreign matters mean materials that are deposited on the substrate but are other than the intended material. In the semiconductor device production process, the foreign matters are unnecessary materials. For example, they include particles deposited on the wafer, metal impurities, etching residues, and bonding agent peeled residues.

The coating film for removing foreign matters according to the present invention is especially preferably used, during the process of bonding wafers using a bonding agent followed by peeling the bonding agent off, for forming the coating film of the present invention before applying the bonding agent, conducting thereafter wafer bonding and peeling steps, and then peel-off the foreign matters (bonding agent residue).

The coating film for removing foreign matters according to the present invention may be used for removing pre-existing foreign matters on a substrate for semiconductor production.

The expression that the coating film for removing foreign matters according to the present invention is soluble in a developer means that, when the coating film is immersed in, or cleaned or the like using the below-mentioned developer, the coating film is dissolved in the developer so that it is not present on the substrate. The term “dissolved (or dissolution)” in the present invention means: when the immersion, cleaning or other treatment is carried out by the method described in the Examples below, at least 90% or more of the thickness of the film originally formed is removed (that is, the thickness of the residual film is 10% or less that of the original film); or at least 95% or more of the thickness of the original film is removed (that is, the thickness of the residual film is 5% or less that of the original film); or at least 99% or more of the thickness of the original film is removed (that is, the thickness of the residual film is 1% or less that of the original film), and most preferably 100% of the thickness of the original film is removed (that is, the thickness of the residual film is 0% of the thickness of the original film (no residual film remains)), from the film formed on the substrate.

It is preferred that the composition contains a cross-linking agent and/or an additive.

### Cross-Linking Agent

It is preferred that the cross-linking agent contains an epoxy group.

The cross-linking agent may contain a compound having at least two epoxy groups. There is no particular limitation to such a compound as long as it is a compound having epoxy groups. The examples thereof include: tris(2,3-epoxypropyl) isocyanurate, 1,4-butanediol diglycidyl ether, 1,2-epoxy-4-(epoxyethyl)cyclohexane, glycerol triglycidyl ether, diethylene glycol diglycidyl ether, 2,6-diglycidyl phenyl glycidyl ether, 1,1,3-tris[p-(2,3-epoxypropoxy)phenyl]propane, 1,2-cyclohexanedicarboxylic acid diglycidyl ester, 4,4′-methylenebis(N,N-diglycidylaniline), 3,4-epoxycyclohexylmethyl-3,4-epoxycyclohexane carboxylate, trimethylol ethane triglycidyl ether and bisphenol-A diglycidyl ether, and pentaerythritol polyglycidyl ether.

Examples of compounds having at least two epoxy groups or epoxy resins having an amino group include YH-434, YH434L (trade name, manufactured by NIPPON STEEL Chemical & Material Co., Ltd.); examples of epoxy resins having a cyclohexene oxide structure include Epolead GT-401, Epolead GT-403, Epolead GT-301, Epolead GT-302, Celloxide 2021, Celloxide 3000 (trade name, manufactured by Daicel Corporation); examples of bisphenol A epoxy resins include EPIKOTE 1001, EPIKOTE 1002, EPIKOTE 1003, EPIKOTE 1004, EPIKOTE 1007, EPIKOTE 1009, EPIKOTE 1010, EPIKOTE 828 (trade name, each of which is manufactured by Yuka Shell Epoxy Kabushiki Kaisha); examples of bisphenol F epoxy resins include EPIKOTE 807 (trade name, manufactured by Yuka Shell Epoxy Kabushiki Kaisha); examples of phenolic novolac epoxy resins include EPIKOTE 152, EPIKOTE 154 (trade name, each of which is manufactured by Yuka Shell Epoxy Kabushiki Kaisha), EPPN 201, EPPN 202 (trade name, each of which is manufactured by Nippon Kayaku Co., Ltd.); examples of cresol novolac epoxy resins include EOCN-102, EOCN-103S, EOCN-104S, EOCN-1020, EOCN-1025, EOCN-1027 (trade name, each of which is manufactured by Nippon Kayaku Co., Ltd.), and EPIKOTE 180S75 (trade name, manufactured by Yuka Shell Epoxy Kabushiki Kaisha); examples of alicyclic epoxy resins include Denacol EX-252 (trade name, manufactured by Nagase Chemtex Corporation), CY175, CY177, CY179 (trade name, each of which is manufactured by CIBA-GEIGY A.G), Araldite CY-182, Araldite CY-192, Araldite CY-184 (trade name, each of which is manufactured by CIBA-GEIGY A.G), EPICLON 200, EPICLON 400 (trade name, each of which is manufactured by DIC Corporation), EPIKOTE 871, EPIKOTE 872 (trade name, each of which is manufactured by Yuka Shell Epoxy Kabushiki Kaisha), and ED-5661, ED-5662 (trade name, each of which is manufactured by Celanese Corporation); and examples of aliphatic polyglycidyl ethers include Denacol EX-611, Denacol EX-612, Denacol EX-614, Denacol EX-622, Denacol EX-411, Denacol EX-512, Denacol EX-522, Denacol EX-421, Denacol EX-313, Denacol EX-314, Denacol EX-321 (trade name, manufactured by Nagase Chemtex Corporation).

The amount of the contained compound having at least two epoxy groups ranges, for example, 5 to 70 parts by mass, or 10 to 60 parts by mass, preferably 15 to 45 parts by mass, relative to 100 parts by mass of the polymer. When the amount of the contained compound having at least two epoxy groups is less than 5 parts by mass, the coating film for removing foreign matters sometimes shows an insufficient degree of cure so that, for example, the coating film would be dissolved in the bonding agent layer to cause intermixing. When the amount of the compound is more than 70 parts by mass, sufficient solubility of the coating film in a developer may not be obtained.

### Additives

The coating film for removing foreign matters according to the present invention may contain light-absorbing compounds, surfactants, adhesion aids, and rheology modifiers as additives.

### Light-Absorbing Compound

There is no particular limitation to the light-absorbing compound as long as it is a compound having absorption at a wavelength of the light used in the exposure. A compound having an aromatic ring structure, such as an anthracene ring, a naphthalene ring, a benzene ring, a quinoline ring, or a triazine ring, is preferably used. From the viewpoint of not lowering the solubility of the coating film for removing foreign matters in a developer, a compound having a phenolic hydroxy group, a carboxyl group, or a sulfonic group, is preferably used.

Examples of a light-absorbing compound having an intense absorption to a light having a wavelength of 248 nm include 1-naphthalenecarboxylic acid, 2-naphthalenecarboxylic acid, 1-naphthol, 2-naphthol, 1-aminonaphthalene, 1-hydroxy-2-naphthalenecarboxylic acid, 3-hydroxy-2-naphthalenecarboxylic acid, 3,7-dihydroxy-2-naphthalenecarboxylic acid, 6-bromo-2-hydroxynaphthalene, 1,2-naphthalenedicarboxylic acid, 1,3-naphthalenedicarboxylic acid, 1,4-naphthalenedicarboxylic acid, 1,5-naphthalenedicarboxylic acid, 1,6-naphthalenedicarboxylic acid, 1,7-naphthalenedicarboxylic acid, 1,8-naphthalenedicarboxylic acid, 2,3-naphthalenedicarboxylic acid, 2,6-naphthalenedicarboxylic acid, 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,6-dihydroxynaphthalene, 2,7-dihydroxynaphthalene, 6-hydroxy-1-naphthalenecarboxylic acid, 1-hydroxy-2-naphthalenecarboxylic acid, 3-hydroxy-2-naphthalenecarboxylic acid, 6-hydroxy-2-naphthalenecarboxylic acid, 1-bromo-2-hydroxy-3-naphthalenecarboxylic acid, 1-bromo-4-hydroxy-3-naphthalenecarboxylic acid, 1,6-dibromo-2-hydroxy-3-naphthalenecarboxylic acid, 3-hydroxy-7-methoxy-2-naphthalenecarboxylic acid, 1-amino-2-naphthol, 1,5-dimercaptonaphthalene, 1,4,5,8-naphthalenetetracarboxylic acid, 3,5-dihydroxy-2-naphthalenecarboxylic acid, 1,4-dihydroxy-2-naphthalenecarboxylic acid, 2-ethoxy-1-naphthalenecarboxylic acid, 2,6-dichloro-1-naphthol, methyl 2-hydroxy-3-naphthalenecarboxylate, methyl 6-hydroxy-2-naphthalenecarboxylate, methyl 3-hydroxy-7-methoxy-2-naphthalenecarboxylate, methyl 3,7-dihydroxy-2-naphthalenecarboxylate, 2,4-dibromo-1-naphthol, 1-bromo-2-naphthol, 2-naphthalenethiol, 4-methoxy-1-naphthol, 6-acetoxy-2-naphthalenecarboxylic acid, 1,6-dibromo-1-naphthol, 2,6-dibromo-1,5-dihydroxynaphthalene, 1-acetyl-2-naphthol, 9-anthracenecarboxylic acid, 1,4,9,10-tetrahydroxyanthracene, and 1,8,9-trihydroxyanthracene.

Examples of a light-absorbing compound having an intense absorption to a light having a wavelength of 193 nm include benzoic acid, 4-methylbenzoic acid, o-phthalic acid, m-phthalic acid, p-phthalic acid, 2-methoxybenzoic acid, isophthalic acid, terephthalic acid, 2-hydroxybenzoic acid, 3-hydroxybenzoic acid, 4-hydroxybenzoic acid, 2-acetoxybenzoic acid, 2-aminobenzoic acid, 3-aminobenzoic acid, 4-aminobenzoic acid, trimesic acid, 1,4-benzenedicarboxylic acid, 2,3-dimethoxybenzoic acid, 2,4-dimethoxybenzoic acid, 2,5-dimethoxybenzoic acid, 2,4-dihydroxybenzoic acid, 2,6-dihydroxybenzoic acid, 3,4-dihydroxybenzoic acid, 3,5-dihydroxybenzoic acid, 4-acetylbenzoic acid, pyromellitic acid, trimesic anhydride, 2-[bis-(4-hydroxyphenyl)-methyl]benzoic acid, 3,4,5-trihydroxybenzoic acid, 2-benzophenonecarboxylic acid, m-phenylbenzoic acid, 3-(4′-hydroxyphenoxy)benzoic acid, 3-phenoxybenzoic acid, phenol, 1,4-dihydroxybenzene, 1,3-dihydroxybenzene, 1,2-dihydroxybenzene, 2-methylphenol, 3-methylphenol, 4-methylphenol, 1,3,5-trihydroxybenzene, 2,2-bis-4-hydroxyphenylpropane, 2-hydroxybiphenyl, 2-aminophenol, 3-aminophenol, 4-aminophenol, and 4-benzyloxyphenol.

For suppressing the sublimation of the above light-absorbing compound during the baking carried out for forming the coating film for removing foreign matters, the light-absorbing compound may be allowed to react with a polymer or a compound having one or more reactive groups before use.

For example, in case of light-absorbing compounds having carboxyl or phenolic hydroxy groups, there may be used a compound obtained by allowing the light-absorbing compound to react with a multifunctional epoxy compound such as tris(2,3-epoxypropyl)isocyanurate, 1,4-butanediol diglycidyl ether, 1,2-epoxy-4-(epoxyethyl)cyclohexane, glycerol triglycidyl ether, diethylene glycol diglycidyl ether, 2,6-diglycidyl phenyl glycidyl ether, 1,1,3-tris[p-(2,3-epoxypropoxy)phenyl]propane, 1,2-cyclohexanedicarboxylic acid diglycidyl ester, 4,4′-methylenebis(N,N-diglycidylaniline), 3,4-epoxycyclohexylmethyl-3,4-epoxycyclohexane carboxylate, trimethylol ethane triglycidyl ether and bisphenol-A diglycidyl ether, and pentaerythritol polyglycidyl ether, or with a polymer containing a structure having epoxy groups such as glycidyl methacrylate. For example, polymers having a unit structure represented by formula (42), (43), or (44) below, and a compound represented by formula (45) below may be given. In formula (45), Ar represents a benzene ring, a naphthalene ring, or an anthracene ring, which is optionally substituted with an alkyl group having 1 to 5 carbon atoms, an alkoxy group having 1 to 5 carbon atoms, a fluorine atom, a chlorine atom, a bromine atom, an iodine atom, a nitro group, a cyano group, a hydroxyl group, a thiol group, a thioalkyl group having 1 to 5 carbon atoms, a carboxyl group, a phenoxy group, an acetyl group, an alkoxycarbonyl group having 1 to 5 carbon atoms, or a vinyl group.

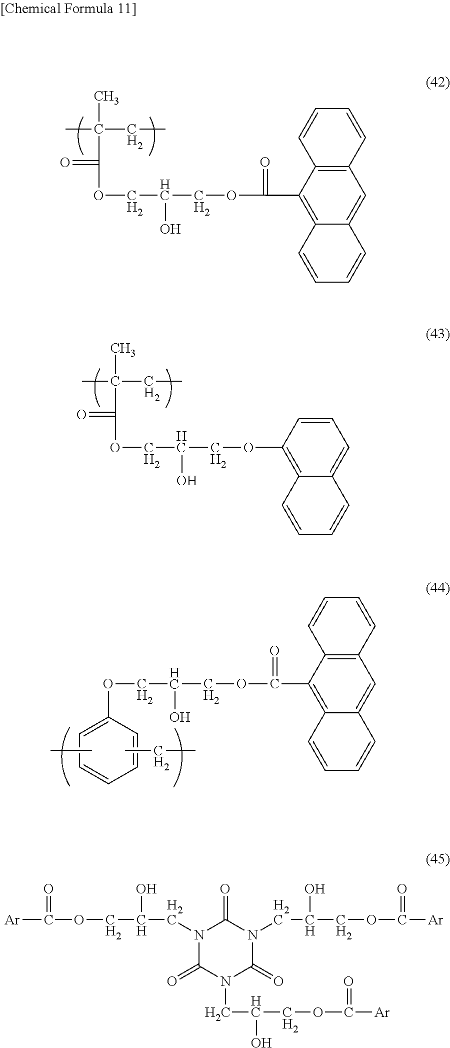

The above-mentioned light-absorbing compounds may be used each alone or two or more thereof in combination. When a light-absorbing compound is used, the amount of the light-absorbing compound contained ranges, for example, 1 to 300 parts by mass, or 1 to 200 parts by mass, or, for example, 1 to 100 parts by mass, or 5 to 100 parts by mass, relative to 100 parts by mass of the polymers. When the amount of the light-absorbing compound is more than 300 parts by mass, the solubility of the coating film for removing foreign matters in a developer is sometimes lowered, or intermixing of the coating film for removing foreign matters with the layer of bonding agent is sometimes caused.

The composition for forming a coating film for removing foreign matters according to the present invention may contain an acid generator. Examples of acid generators include thermal acid generators, such as 2,4,4,6-tetrabromocyclohexadienone, benzoin tosylate, 2-nitrobenzyl tosylate, and other organic sulfonic acid alkyl esters; and photo-acid generators, such as bis(4-tert-butylphenyl)iodonium trifluoromethanesulfonate, triphenylsulfonium trifluoromethanesulfonate, phenyl-bis(trichloromethyl)-s-triazine, benzoin tosylate, and N-hydroxysuccinimide trifluoromethanesulfonate. The amount of the acid generator added is, if necessary, 10% by mass or less, preferably 3% by mass or less, based on the mass of the solid content of the composition for forming a coating film for removing foreign matters.

In the composition for forming a coating film for removing foreign matters according to the present invention, for the purpose of increasing the dissolution rate into a developer, a polyhydric phenol compound or a carboxyl group-containing compound may be added. There is no particular limitation to the compound, and the compound includes, for example, polyhydric phenols, such as tris-hydroxyphenylethane, bisphenol-A, bisphenol-S, 4,4′-isopropylidene-di-o-cresol, 5-tert-butylpyrogallol, hexafluorobisphenol-A, 3,3,3′,3′-tetramethyl-1,1′-spirobisindan-5,5′,6,6′-tetrol, 4,4′-(9-fluorenylidene)diphenol, bisphenol-AP, bisphenol-P, 5-α,α-dimethyl-4-hydroxybenzylsalicylic acid, α,α,α′-tris(4-hydroxyphenyl)-1-ethyl-4-isopropylbenzene, and 5,5′-di-tert-butyl-2,2′,4,4′-tetrahydroxybenzophenone; polycarboxylic acids, such as pyromellitic acid, phthalic acid, trimellitic acid, 4-sulfophthalic acid, benzenehexacarboxylic acid, 2,3-naphthalenedicarboxylic acid, 4-hydroxyphthalic acid, 3,4-dihydroxyphthalic acid, 4,5-dihydroxyphthalic acid, 3,3′-,4,4′-biphenyltetracarboxylic acid, 3,3′-,4,4′-benzophenonetetracarboxylic acid, 3,3′-,4,4′-diphenyl ether tetracarboxylic acid, 3,3′-,4,4′-diphenyl sulfone tetracarboxylic acid, 1,2,3,4-cyclobutanetetracarboxylic acid, 1,2-dimethyl-1,2,3,4-cyclobutanetetracarboxylic acid, 1,2,3,4-tetramethyl-1,2,3,4-cyclobutanetetracarboxylic acid, 1,2,3,4-cyclopentanetetracarboxylic acid, 1,2,3,4-cyclohexanetetracarboxylic acid, and 3,4-dicarboxy-1,2,3,4-tetrahydro-1-naphthalenesuccinic acid; carboxylic acid- or carboxylic anhydride-containing polymers, such as polyacrylic acid, polymethacrylic acid, polyamic acid, and polymaleic anhydride. The amount of the above-mentioned compound added is, if necessary, 20% by mass or less, preferably 10% by mass or less, based on the mass of the solid content of the composition for forming a coating film for removing foreign matters.

For the purpose of controlling the dissolution rate into a developer, a compound having a carboxyl group or phenolic hydroxy group protected by a group such as a tert-butyl group, a tetrahydropyranyl group, a 1-ethoxyethyl group, or a trimethylsilyl group, which are readily decomposed in the presence of an acid, may also be added to the composition for forming a coating film for removing foreign matters according to the present invention.

Such compounds include, for example, di-tert-butyl malonate, tert-butyl acetate, tert-butyl propionate, tert-butyl acetoacetate, tert-amyl acetate, benzoic acid-tert-butyl ester and tert-butyl pivalate. They also include the compounds of the following formulae (46) to (54).

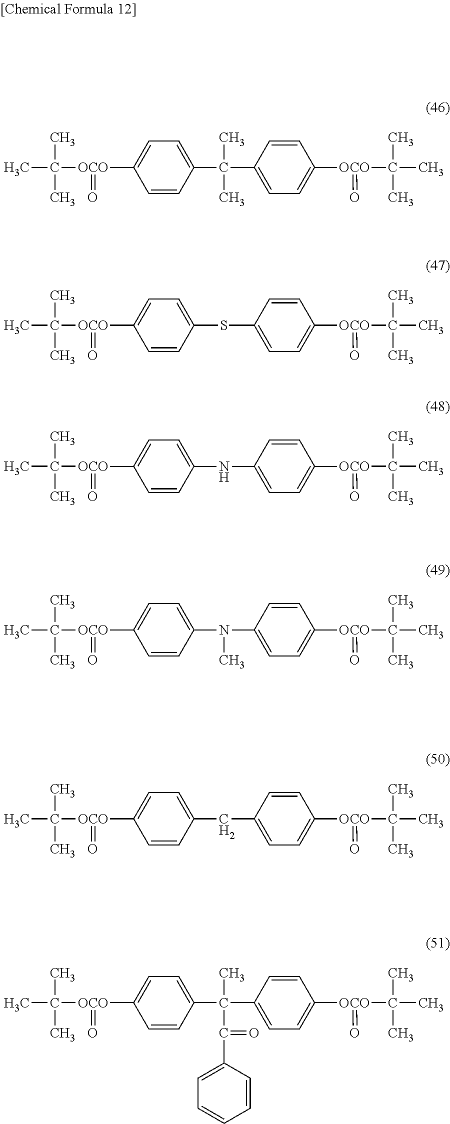

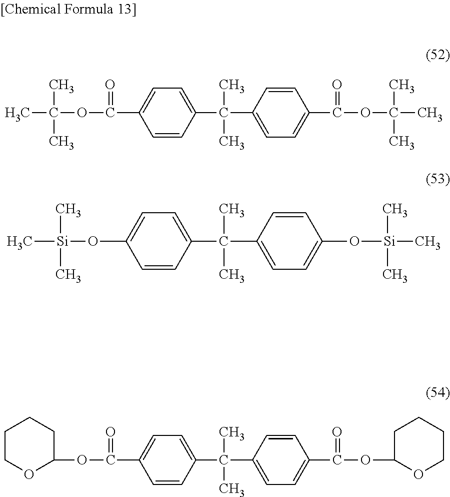

The above-mentioned compounds may easily form a carboxyl group or a phenolic hydroxy group in the presence of an acid, providing a compound having an increased solubility in an alkaline developer.

Therefore, it is preferred that the above-mentioned compound is added, together with a photo-acid generator, to the composition for forming a coating film for removing foreign matters. That is, with regard to the composition for forming a coating film for removing foreign matters containing a photo-acid generator and the above-mentioned compound having a carboxyl group or phenolic hydroxy group protected by a group that is easily decomposed in the presence of an acid, the acid generated from the photo-acid generator due to the exposure in the exposed region of the coating film for removing foreign matters regenerates the carboxyl group or phenolic hydroxy group of the compound having a carboxyl group or phenolic hydroxy group protected by a group that is easily decomposed in the presence of an acid. As the result, the solubility of the exposed region of the coating film for removing foreign matters in an alkaline solution is increased. In contrast, in the unexposed region, there is no change in the compound having a carboxyl group or phenolic hydroxy group protected by a group that is easily decomposed in the presence of an acid. Hence, the solubility of the unexposed region of the coating film for removing foreign matters in an alkaline solution is not increased. As such, it becomes possible to cause a difference in the solubility in an alkaline developer between the exposed region and the unexposed region of the coating film for removing foreign matters after the exposure by the use of the compound having a carboxyl group or phenolic hydroxy group protected by a group that is easily decomposed in the presence of an acid and the photo-acid generator in combination, which facilitates the pattern formation by development.

When the above-mentioned compound having a carboxyl group or phenolic hydroxy group protected by a group that is easily decomposed in the presence of an acid is used, the amount of the compound contained ranges, for example, 50 to 1 part by mass, or 30 to 5 parts by mass, or, for example, 20 to 10 parts by mass, relative to 100 parts by mass of the polymers. When a photo-acid generator is used together with the compound having a carboxyl group or phenolic hydroxy group protected by a group that is easily decomposed in the presence of an acid, the amount of the photo-acid generator contained ranges, for example, 0.1 to 30 parts by mass, or 0.5 to 20 parts by mass, or, for example, 1 to 10 parts by mass, relative to 100 parts by mass of the compound having a carboxyl group or phenolic hydroxy group protected by a group that is easily decomposed in the presence of an acid.

### Surfactant

The composition for forming a coating film for removing foreign matters according to the present invention may contain a surfactant. Examples of surfactants include nonionic surfactants, e.g., polyoxyethylene alkyl ethers, such as polyoxyethylene lauryl ether, polyoxyethylene stearyl ether, polyoxyethylene cetyl ether, and polyoxyethylene oleyl ether; polyoxyethylene alkylaryl ethers, such as polyoxyethylene octylphenol ether and polyoxyethylene nonylphenol ether; polyoxyethylene-polyoxypropylene block copolymers; sorbitan fatty acid esters, such as sorbitan monolaurate, sorbitan monopalmitate, sorbitan monostearate, sorbitan monooleate, sorbitan trioleate, and sorbitan tristearate; and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine surfactants, such as EFTOP EF301, EF303, EF352 (trade name, manufactured by Tohchem Products Co., Ltd.), MEGAFACE F171, F173 (trade name, manufactured by DIC Corporation), Fluorad FC430, FC431 (trade name, manufactured by Sumitomo 3M), and AsahiGuard AG710, Surflon S-382, SC101, SC102, SC103, SC104, SC105, SC106 (trade name, manufactured by Asahi Glass Co., Ltd.), and organosiloxane polymer KP341 (trade name, manufactured by Shin-Etsu Chemical Co., Ltd.). The amount of the surfactant incorporated ranges generally 0.2% by mass or less, preferably 0.1% by mass or less, based on the total mass of the all components of the composition for forming a coating film for removing foreign matters according to the present invention. These surfactants may be added each alone or two or more thereof in combination.

### A Coating Film for Removing Foreign Matters and a Method for Producing a Coating Film for Removing Foreign Matters

The composition for forming a coating film for removing foreign matters according to the present invention is applied onto a semiconductor substrate (for example, a silicon/silicon dioxide coated substrate, a silicon nitride substrate, a glass substrate, or an ITO substrate) by an appropriate application method, such as a spinner, a coater, or immersion, and then baked to form a coating film for removing foreign matters. The conditions for baking are appropriately selected from those at a baking temperature of 80 to 300° C. for a baking time of 0.3 to 60 minutes.

The coating film for removing foreign matters according to the present invention generally has a thickness of 1 μm to 5 nm, preferably 500 to 10 nm, most preferably 300 to 15 nm.

The dissolution rate of the coating film for removing the formed foreign matters in a developer for photoresist ranges 0.1 to 50 nm per second, preferably 0.2 to 40 nm per second, more preferably 0.3 to 20 nm per second. A dissolution rate smaller than the above value would require a prolonged period of time for removing the coating film for removing foreign matters, and lower the productivity.

The coating film for removing foreign matters formed from the composition for forming a coating film for removing foreign matters according to the present invention permits controlling the dissolution rate thereof in a developer by changing the baking conditions for the formation of the film. At a constant baking time, formation of a coating film for removing foreign matters having a smaller dissolution rate in a developer is possible as the baking temperature is made higher.

The coating film for removing foreign matters according to the present invention, after having been formed, may be subjected to exposure. The exposure may be made over the entire surface of a wafer, or may be made through a mask having a predetermined pattern. KrF excimer laser (wavelength: 248 nm), ArF excimer laser (wavelength: 193 nm) and F2 excimer laser (wavelength: 157 nm) may be used for exposure. After the exposure, if necessary, post exposure baking (PEB: Post Exposure Bake) may be performed.

Then, the coating film for removing foreign matters is removed using a developer. Examples of developers include alkaline aqueous solutions, e.g., aqueous solutions of an alkali metal hydroxide, such as potassium hydroxide or sodium hydroxide; aqueous solutions of a quaternary ammonium hydroxide, such as tetramethylammonium hydroxide, tetraethylammonium hydroxide, or choline; and aqueous solutions of an amine, such as ethanolamine, propylamine, or ethylenediamine. Further, for example, a surfactant may be added to the above developer. The conditions for removing the coating film for removing foreign matters are appropriately selected from those at a temperature of 5 to 50° C. for a time of 2 to 500 seconds, or 3 to 400 seconds.

The coating film for removing foreign matters formed from the composition for forming a coating film for removing foreign matters according to the present invention may be easily peeled off at room temperature (for example, at 25° C.) using a generally used 2.38% by mass aqueous solution of tetramethylammonium hydroxide.

### Method for Removing Foreign Matters

The method for removing foreign matters according to the present invention is a method for removing foreign matters, which comprises the steps of: applying the above-described composition onto a substrate and baking the applied composition to form a coating film; allowing foreign matters to form on the film; and letting a developer act on the film to remove the film.

After the step of forming the coating film, the method may further comprise the step of forming a bonding layer and then peeling the bonding layer off. The foreign matters may be a peeled residue after forming the bonding layer.

The method for removing foreign matters according to the present invention may be a method for removing foreign matters already present on a substrate for semiconductor production. For example, as in WO 2017/056746 A1 and WO 2020/008965 A1, in a process for forming a substrate treatment film on the surface of the semiconductor substrate and removing foreign matters from this substrate surface, compositions for forming substrate treatment films and methods for treating substrates, which would permit efficient removal of minute particles from a substrate surface and easy removal of the formed substrate treatment film from the substrate surface, are disclosed. The composition for forming a coating film of the present application may be used in a similar method/use as mentioned above.

A specific example of the above is described below. In this application example, the composition for forming a coating film for removing foreign matters described above is used as a composition for forming the coating film on a wafer for semiconductor production. First, the step of forming the coating film is performed. Thus, the composition for forming a coating film for removing foreign matters was applied on a wafer for semiconductor production to form a coating film. A wafer for semiconductor production may be a so-called plane substrate (flat), which is in an unprocessed state or with various films formed thereon, or it may be a wafer with other shapes such as wiring processed, for the semiconductor device production. Coating methods include, for example, spin coating, cast coating, roll coating, and the like. The coated film is then heated (baked) and/or depressurized to efficiently remove a part or all of the solvent contained in the coated film, thereby accelerating solidification and/or curing of the solid content contained in the coated film. Herein, the term “solidification” means becoming solid, and the term “curing” means an increase in molecular weight (e.g., cross-linking, polymerization, etc.) due to the linkage of molecules. As such, a coating film is formed. In this process, particles adhering to the pattern, and the like, are incorporated by the coating film and efficiently separated from the pattern, and the like. Next, a step of removing the coating film is performed. Thus, the coating film is entirely removed from the semiconductor production wafer by supplying onto the coating film a removal solution that dissolves the coating film. As a result, particles are removed from the semiconductor production wafer along with the coating film. Water, organic solvents, and alkaline aqueous solutions may be used as the removal solution, of which water and alkaline aqueous solutions are preferred, and alkaline aqueous solutions are more preferred.

Examples of the substrates include glass and metal-containing compounds or semi-metal-containing compounds. Examples of metal-containing compounds or semi-metal-containing compounds include ceramics which are sintered products having a metal oxide as a basic component and being obtained by sintering by heat treatment at high temperatures; semiconductors, such as silicon, inorganic solid materials, such as shaped articles of an inorganic compound, e.g., a metal oxide or a semi-metal oxide (such as a silicon oxide or alumina); a metal carbide or a semi-metal carbide; a metal nitride or a semi-metal nitride (such as a silicon nitride); or a metal boride or a semi-metal boride; aluminum; nickel titanium; and stainless steel (such as SUS304, SUS316, and SUS316L); however, preferred is a silicon substrate (for example, a silicon wafer for semiconductor for use in the production of a semiconductor device).

### Method for Treating a Substrate

The method for treating a substrate comprises the steps of: applying the above-described composition onto a substrate and baking the applied composition to form a coating film; forming a bonding layer on the film; temporarily bonding another substrate to the substrate; peeling the another substrate off; and peeling the film off using a developer.

The method for treating a substrate of the present invention is applied to, for example, the so-called step of temporary bonding of wafer.

### Layer of Bonding Agent

The layer of bonding agent is formed using a known bonding agent and method. As a bonding agent, a wafer temporarily bonding agent of an application type described in, for example, WO 2015/190438 A1, a temporarily bonding material of Thin Materials AG (Nissan Chemical Industries, Ltd.), a semiconductor wafer temporarily bonding material manufactured by Toray Industries Inc., or WaferBOND (registered trademark) CR-200, HT-10.10 (manufactured by Brewer Science, Inc.) may be used, or a tape-form bonding agent (for example, a back-grinding tape (e.g., 3MTM temporarily fixing adhesive tape ATT-4025 (3M Japan Limited), E Series, P Series, S Series (trade name, manufactured by Lintec Corporation), or ICROS Tape (registered trademark) (manufactured by Mitsui Chemicals Tohcello, Inc.)), or a dicing tape (for example, Solvent-resistant Dicing Tape (trade name, manufactured by Nitto Denko Corporation), heat-sensitive adhesive sheet Intelimer (registered trademark) tape (manufactured by Nitta Corporation), or Intelimer (registered trademark) tape (manufactured by Anchor Techno, Ltd.)) may be used.

A bonding agent for wafer applied to a specific wafer handling system (for example, Zero Newton (registered trademark), Tokyo Ohka Kogyo Co., Ltd.) may be used.

For example, the back-grinding tape is comprised of a substrate film, an adhesive layer, and a release film. In the substrate film, a soft thermoplastic film, such as an ethylene-vinyl acetate copolymer (EVA), has been used; however, for the purpose of improving the supporting properties for a wafer, the use of a rigid stretched film, such as polyethylene terephthalate (PET), is being attempted. Thereafter, further improvements have been made, and a design of lamination of two types of films having different moduli, for example, a design of lamination of PET and an ethylene copolymer and a design of lamination of polypropylene (PP) and an ethylene copolymer have been reported.

The adhesive is generally of an acrylic type. With respect to acrylic adhesives, a design has been known such that crosslinking is caused by reacting a curing agent with an acrylic copolymer from a monomer having a low glass transition temperature, such as butyl acrylate, as the major raw material. The back-grinding tape is bonded to the wafer circuit surface, and therefore, there is a concern about contamination derived from the adhesive after peeling the tape. For this reason, there is a report of a design using an emulsion type adhesive with the expectation of removal of potentially remaining adhesive by rinsing it with water; however, it has been difficult to completely remove the remaining adhesive. By forming the coating film for removing foreign matters according to the present invention on the circuit surface and then forming a bonding layer, it is now possible to completely remove foreign matters (bonding agent residue) caused in the subsequent peeling step by cleansing using a developer, while keeping the wiring portions including circuits undamaged.

### Method for Producing a Laminated Substrate

A laminated substrate having a substrate-the film-bonding layer-substrate construction may be produced through a process comprising the steps of: applying the above-described composition onto a substrate and baking the applied composition to form a coating film; forming a bonding layer on the film; and bonding another substrate to the substrate. It is preferred that one substrate is a semiconductor substrate and another one is a supporting substrate for maintaining the shape of the semiconductor substrate. It is also preferred that the bonding layer enables, for example, the semiconductor substrate and the supporting substrate to be peeled off from each other. The bonding layer is as described above.

### EXAMPLES

Hereinbelow, the present invention will be described in more detail with reference to the following Examples, which should not be construed as limiting the scope of the present invention.

### Example 1

### Preparation of Composition for Forming a Coating Film for Removing Foreign Matters

To 8.1 g of a naphthol cresol novolac (MN8280G, weight average molecular weight 5,000)(manufactured by Asahi Yukizai Co., Ltd.) were added 0.27 g of 4,4′-methylene bis(diglycidylaniline) (manufactured by NIPPON STEEL Chemical & Materials Co. Ltd), 43.5 g of propylene glycol monomethyl ether, and 13.1 g of propylene glycol monomethyl ether acetate. The resultant mixture was stirred at room temperature for 30 minutes to prepare solution [1] of the composition for forming a coating film for removing foreign matters comprising the polymer shown in the formula below.

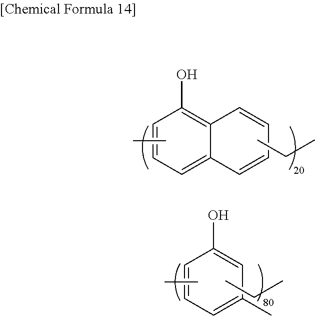

### Evaluation of the Composition for Forming a Coating Film for Removing Foreign Matters

Solution [1] of the composition for forming a coating film for removing foreign matters was applied onto a silicon wafer substrate using a spinner, and then baked on a hotplate at 200° C. for 60 seconds to form a coating film for removing foreign matters having a thickness of 40 nm.

Then, the dissolution rate of the coating film for removing foreign matters in a developer (trade name NMD-3, manufactured by Tokyo Ohka Kogyo Co., Ltd.) was determined using a resist development analyzer (manufactured by Litho Tech Japan Co., Ltd.). The temperature of the atmosphere surrounding the analyzer was 25° C. The coating film for removing foreign matters formed at a baking temperature of 150° C. for a baking time of 60 seconds had a dissolution rate of 3.3 nm per second. The coating film for removing foreign matters formed at a baking temperature of 155° C. for a baking time of 60 seconds had a dissolution rate of 2.8 nm per second, the coating film for removing foreign matters formed at a baking temperature of 160° C. for a baking time of 60 seconds had a dissolution rate of 1.8 nm per second, and the coating film for removing foreign matters formed at a baking temperature of 165° C. for a baking time of 60 seconds had a dissolution rate of 0.9 nm per second. In other words, the coating film for removing foreign matters formed at a baking temperature of 150° C. for a baking time of 60 seconds can be completely removed in 12 seconds, the coating film for removing foreign matters formed at a baking temperature of 155° C. for a baking time of 60 seconds can be completely removed in 14 seconds, the coating film for removing foreign matters formed at a baking temperature of 160° C. for a baking time of 60 seconds can be completely removed in about 22 seconds, and the coating film for removing foreign matters formed at a baking temperature of 165° C. for a baking time of 60 seconds can be completely removed in about 44 seconds. Therefore, the foreign matters present on the above coating film for removing foreign matters can also be removed together.

### Example 2

### Synthesis of a Polyamic Acid

17.8 g of 4,4′-(hexafluoroisopropylidene)diphthalic dianhydride, 3.12 g of 3,5-diaminobenzoic acid, and 4.92 g of bis(4-aminophenyl sulfone) were reacted in 145.6 g of propylene glycol monomethyl ether at 80° C. for 20 hours to obtain a solution [C] containing a polyamic acid. GPC analysis of the obtained polyamic acid showed that the weight average molecular weight Mw was 8,600 (determined by standard polystyrene conversion), and the number average molecular weight Mn was 5,200.

### Synthesis of a Light-Absorbing Compound

19.0 g of 3,7-dihydroxy-2-naphthoic acid, 10 g of tris(2,3-epoxypropyl) isocyanurate, and 0.552 g of benzyltriethylammonium chloride were reacted in 118 g of cyclohexanone at 130° C. for 24 hours to obtain solution [a] containing a light-absorbing compound.

### Preparation of a Composition for Forming a Coating Film for Removing Foreign Matters

To 25.0 g of solution [C] containing polyamide acid were added 4.15 g of light-absorbing compound solution [a], 1.13 g of 4,4′-methylenebis(N,N-diglycidylaniline), 0.825 g of 3,7-dihydroxynaphthoic acid, 0.124 g of triphenylsulfonium trifluoromethanesulfonate, 82.8 g of propylene glycol monomethyl ether, 127 g of propylene glycol monomethyl ether acetate, and 10.0 g of cyclohexanone. The resultant mixture was stirred at room temperature for 30 minutes to prepare solution [5] of composition for forming a coating film for removing foreign matters.

### Evaluation of the Composition for Forming a Coating Film for Removing Foreign Matters

Solution [5] of the composition for forming a coating film for removing foreign matters was applied onto a silicon wafer substrate using a spinner, and then baked on a hotplate at 175° C. for 60 seconds to form a coating film for removing foreign matters having a thickness of 40 nm.

Then, the dissolution rate of the coating film for removing foreign matters in a developer (trade name NMD-3, manufactured by Tokyo Ohka Kogyo Co., Ltd.) was determined using a resist development analyzer (manufactured by Litho Tech Japan Co., Ltd.). The temperature of the atmosphere surrounding the analyzer was 25° C. The coating film for removing foreign matters formed at a baking temperature of 170° C. for a baking time of 60 seconds had a dissolution rate of 2.35 nm per second, and the coating film for removing foreign matters formed at a baking temperature of 175° C. for a baking time of 60 seconds had a dissolution rate of 2.00 nm per second. The coating film for removing foreign matters formed at a baking temperature of 180° C. for a baking time of 60 seconds had a dissolution rate of 1.82 nm per second.

In other words, the coating film for removing foreign matters formed at a baking temperature of 170° C. for a baking time of 60 seconds can be completely removed in 17 seconds, the coating film for removing foreign matters formed at a baking temperature of 175° C. for a baking time of 60 seconds can be completely removed in 20 seconds, the coating film for removing foreign matters formed at a baking temperature of 180° C. for a baking time of 60 seconds can be completely removed in about 22 seconds. Therefore, the foreign matters present on the above coating film for removing foreign matters can also be removed together.

### Evaluation of the Storage Stability

The solutions of the composition for forming a coating film for removing foreign matters in Examples 1 and 2 were stored at −20° C. to +35° C. for one month. Thereafter, the solutions were brought to room temperature, applied on a silicon wafer substrate using a spinner, baked on a hot plate at 120° C. for 60 seconds, and the change in film thickness was investigated. As a result, Example 2 showed a decrease in film thickness from the initial thickness after one month of storage at 35° C., while no change in film thickness was observed in Example 1.

Solutions of the composition for forming a coating film for removing foreign matters in Examples 1 and 2 were stored at −20° C. to +35° C. for one month. Thereafter, the solutions were brought to room temperature, applied on a silicon wafer substrate using a spinner, baked on a hot plate at 120° C. for 60 seconds, and the development speed with a development time of 10 seconds was investigated. It was found that both of the solutions had a sufficiently high development speed and had a sufficient capacity to remove foreign matters. Accordingly, Example 1 demonstrated not only the capacity to remove foreign matters but also a good storage stability.

### Industrial Applicability

The present invention relates to a composition for forming a coating film for removing foreign matters, a method for removing foreign matters on a substrate, a method for treating a substrate, and a method for producing a laminated substrate, which permit removing foreign matters formed on a substrate in a simple and easy way. According to the present invention, it is possible to provide a composition for forming a coating film for removing foreign matters, which is preferably used in the semiconductor step of temporary bonding of wafer in the production of a semiconductor device.

1. A composition for forming a coating film for removing foreign matters, which comprises a polymer and a solvent, and is capable of forming a coating film that is soluble in a developer,
wherein the polymer is selected from a phenolic hydroxy group-containing polymer and a carboxy group-containing polymer, and the composition contains the polymer in an amount of 50% by mass or more relative to the total solid content in the composition.

2. The composition according to claim 1, wherein the phenolic hydroxy group-containing polymer is a phenolic novolac or a polyhydroxystyrene derivative.

3. The composition according to claim 1, wherein the carboxy group-containing polymer is selected from (meth)acrylic resin, polyvinyl benzoic acid or carboxymethyl cellulose.

4. The composition according to claim 1, wherein the composition comprises a cross-linking agent and/or an additive.

5. The composition according to claim 4, wherein the cross-linking agent comprises an epoxy group.

6. A coating film for removing foreign matters, which is a baked product of an applied film of the composition according to claim 1.

7. A method for removing foreign matters, comprising the steps of:
applying the composition according to claim 1 onto a substrate and baking the applied composition to form a coating film;
allowing foreign matters to be formed on the coating film, and
removing the coating film together with the foreign matters using a developer.

8. The method according to claim 7, wherein the step of allowing foreign matters to be formed includes the step of forming a bonding layer on the coating film, and the step of peeling the bonding layer off thereafter.

9. The method according to claim 8, wherein the foreign matters are a peeled residue of the bonding layer.

10. A method for treating a substrate, comprising the steps of:
applying the composition according to claim 1 onto a first substrate and baking the applied composition to form a coating film;
forming a bonding layer on the coating film;
temporarily bonding a second substrate to the first substrate through the bonding layer;
peeling the second substrate off from the first substrate; and
removing the coating film remaining on the first substrate after peeling off the second substrate, together with the bonding layer, using a developer.

11. A method for producing a laminated substrate, comprising the steps of:
applying the composition according to claim 1 onto a first substrate and baking the applied composition to form a coating film;
forming a bonding layer on the coating film, and
bonding a second substrate to the first substrate.

12. A composition, which is used for removing foreign matters on a substrate for semiconductor production,
wherein the composition comprises a polymer and a solvent, the polymer is selected from a phenolic hydroxy group-containing polymer and a carboxy group-containing polymer, and the composition contains the polymer in an amount of 50% by mass or more relative to the total solid content in the composition.

13. The composition according to claim 12, wherein the composition contains a cross-linking agent and/or an additive.

14. A composition, which is used for removing foreign matters on a substrate for semiconductor production,
wherein the composition comprises a polymer and a solvent, and the polymer is a polyamide acid having a structural unit derived from (a) a tetracarboxylic dianhydride compound and (b) a diamine compound having at least one carboxyl group.

15. A method for removing foreign matters, comprising the steps of:
applying the composition according to claim 12 onto a substrate carrying foreign matters and baking the applied composition to form a coating film containing foreign matters, and
removing the coating film together with the foreign matters using a developer.
